(19) United States
(12) Patent Application Publication
(10) Pub. No.: US 2022/0361344 A1
(43) Pub. Date: Nov. 10, 2022

(54) EXPLOSION-PROOF HOUSING WITH A REINFORCING FRAME

(71) Applicant: R. STAHL SCHALTGERÄTE GMBH, Waldenburg (DE)

(72) Inventors: Holger SEMRAU, Satteldorf (DE); Elena KONDRUS, Künzelsau (DE)

(21) Appl. No.: 17/618,757

(22) PCT Filed: Jun. 10, 2020
(86) PCT No.: PCT/EP2020/066100

§ 371 Date: Dec. 13, 2021

(30) Foreign Application Priority Data
Jun. 13, 2019 (DE) 10 2019 116 164.9

(51) Int. Cl. H05K 5/00; H05K 5/02; H05K 5/03; A62C 3/16

(52) U.S. Cl. CPC H05K 5/0004; H05K 5/0217; H05K 5/03; A62C 3/16

(57) ABSTRACT

The invention relates to an explosion-proof housing (10) with a housing body (11) which delimits an interior (13) and has a housing opening (14). The housing opening (14) can be closed by means of a cover (17). In the closed position of the cover (17), a flameproof gap (18) is formed between the housing body (11) and in particular a housing flange (15) of the housing body (11) and the cover (17). The housing body (11) has a plurality of housing walls (12), which have such a low wall thickness (s) that the housing walls (12) would not withstand the pressure of an explosion in the interior (13). The housing body (11) is therefore reinforced by a reinforcing frame (30) arranged outside the interior (13). The reinforcing frame (30) has a ring frame part (31) that is arranged adjacently to the housing opening (14) and fully surrounds the housing body (11) in an annular fashion. In particular, the ring frame part (31) directly adjoins the housing flange (15).

### CROSS-REFERENCE TO RELATED APPLICATIONS

This application is a National Stage of PCT Application No. PCT/EP2020/066100 filed on Jun. 10, 2020, which claims priority to German Patent Application No. 10 2019 116 164.9 filed on Jun. 13, 2019 and entitled “EXPLOSION-PROOF HOUSING WITH A REINFORCING FRAME”, the contents each of which are incorporated herein by reference thereto.

### BACKGROUND

The invention refers to an explosion-proof housing having an interior that is enclosed in an explosion-proof manner relative to the environment of the housing. In the interior potential ignition sources can be arranged that could lead to an ignition of an explosive atmosphere in the environment. Ignition sources can be, for example, electrical and/or electronic devices or operating means. Such devices or operating means can be safely operated in the interior of the explosion-proof housing. The explosion-proof housing avoids an ignition of the explosive atmosphere in the environment of the housing outside the interior, even in the case if flames, hot gases, sparks, light arcs or the like are created in the interior.

US 2011/0303676 A1 discloses an explosion-proof housing having metallic housing walls. At least one additional reinforcing element can be provided in order to improve the stability of the housing walls. The reinforcing element can have the form of a bracket. Multiple reinforcing elements can be connected by means of threaded rods.

CN 203951114 U describes a housing that comprises reinforcing ribs on a housing cover for reinforcement.

In general the problem exists in explosion-proof housings that the housing structure and the flameproof condition of housing gaps and openings related therewith has to remain intact, also if an explosion occurs in the interior of the housing and pressure is suddenly applied to the housing. The explosion-proof housing has to withstand the explosion pressure without being deformed or damaged in a manner that the explosion-proof condition is abolished. For this reason the housing walls of an explosion-proof housing are usually configured in a very stable manner. For example, housing walls of a housing body can be a cast part limiting an interior, wherein the housing opening in the housing body is rigidly closed by means of a respective stable cover, particularly a steel cover. Such explosion-proof housings are very heavy and very expensive due to the used amount of material.

Thus, it can be considered as object of the invention to provide an explosion-proof housing that can be manufactured simply and easily and concurrently provides a high amount of security.

### BRIEF SUMMARY

This object is solved by means of an explosion-proof housing. Disclosed is an explosion-proof housing, including: a housing body that delimits an interior and that includes a housing opening through which the interior is accessible; a reinforcing frame that is arranged on an outside of the housing body and includes a ring frame part that completely surrounds the housing body in a ring-shaped manner adjacent to the housing opening; a cover that abuts against the housing body in a closing position, such that a flameproof gap is formed between the cover and the housing body.

The explosion-proof housing according to the invention has a housing body limiting an interior. The housing body can have multiple housing walls that can be rigidly connected with one another, e.g. by means of an adhesive bond or a substance bond. The housing walls can be connected with each other by welding, brazing or gluing. The housing body has a housing opening on one side. The access to the interior is possible through the housing opening. In the interior at least one ignition source can be arranged, e.g. one or more electrical and/or electronic devices or operating means. By means of the explosion-proof housing, the at least one ignition source can be separated from an explosive atmosphere in the environment of the housing outside the interior.

The explosion-proof housing can be configured in an appropriate explosion-proof category. For example, the explosion-proof housing corresponds to the explosion-proof category flameproof enclosure (Ex d) according to one of the standards EN 60079-1 or IIC 60079-1.

The explosion-proof housing has a reinforcing frame that is arranged on the outside on the housing body. The reinforcing frame is arranged completely outside the interior. The reinforcing frame can be releasably or non-releasably attached to the housing body, for example. The releasable connection can be particularly realized by a screw connection. The non-releasable connection can be realized, for example, by an adhesive bond or a substance bond, e.g. by means of welding, gluing, brazing or an arbitrary combination thereof. The non-releasable connection can be realized in addition or as an alternative also be mechanical means, e.g. by means of rivets.

The reinforcing frame preferably forms a continuous structure that can be configured from individual frame struts. The frame struts can be configured as hollow profile struts and can particularly have a rectangular or square or another polygonal cross-section.

In addition, a cover is part of the explosion-proof housing. The cover can be brought into a closing position. In the closing position the cover abuts against the housing body and limits together with a section of the housing body a flameproof gap adjacent to the housing opening. The flameproof gap is preferably configured as flat gap and can extend along one plane. Gases can flow through the flameproof gap between the interior and the environment of the housing. The gas flow path allowed because of the flameproof gap is dimensioned such that hot gases, sparks, flames, light arcs or the like are sufficiently cooled or extinguished prior to reaching the environment when exiting from the interior. In doing so, it is ensured that the explosive atmosphere in the environment of the housing cannot be ignited, even if in the interior of the housing an explosion occurs or sparks or flames or hot gases or light arcs are created. To achieve this the flameproof gap can comprise, for example, a small gap cross-section area and orthogonal to the gap cross-section area a sufficiently long gap length.

The reinforcing frame comprises a ring frame part that completely encloses the housing opening in a ring-shaped manner. Because the ring frame part of the reinforcing frame completely surrounds the housing opening in a ring-shaped manner, particularly in the range of the flameproof gap, a very good reinforcement of the housing body is achieved. If an explosion occurs in the interior, it is avoided by means of the ring frame part that the housing body deforms adjacent to the flameproof gap in a manner, such that the flameproof condition is affected or abolished.

Because of the reinforcing frame, the walls of the housing body can be configured with minor wall thicknesses that would otherwise—without the reinforcing frame—not withstand the explosion pressure. The reinforcing frame reinforces the housing body and thereby provides sufficient strength or stability in order to guarantee the explosion protection of the housing, also in case of an explosion in the interior.

Preferably the reinforcing frame or at least the ring frame part of the reinforcing frame is not connected with the cover and/or does not abut against the cover. Particularly the reinforcing frame does not serve to delimit the flameproof gap. The flameproof gap is delimited between cover and housing body.

Preferably the explosion-proof housing comprises at least one pressure relief device. The at least one pressure relief device provides at least one flameproof gas flow path between the interior and the environment. The at least one flameproof gas flow path is provided in addition to the gas flow path through the flameproof gap. The at least one pressure relief device can be arranged in a wall of the housing body and/or in the cover.

It is in addition advantageous, if the reinforcing frame is free from sections of the at least one flameproof gas flow path that is provided by the at least one pressure relief device. Frame struts of the reinforcing frame are thus not passed by the gas flow path.

In another embodiment the explosion-proof housing is free of pressure relief devices. A gas flow connection between the interior and the environment outside of the housing is exclusively provided by the flameproof gap.

In a preferred embodiment the reinforcing frame can have at least one rib frame part that is connected with the ring frame part. The rib frame part extends outside of a plane that is defined by the ring frame part. For example, the at least one rib frame part extends along a plane that extends obliquely or orthogonal relative to the plane along which the housing opening or the cover extends. The at least one rib frame part can abut at one or multiple locations against the housing body. The rib frame part projects preferably not into the housing opening or does not bridge the housing opening on the side from which the cover is arranged on the housing body, such that the access to the interior is not impeded by the at least one rib frame part.

In an embodiment each rib frame part or at least one rib frame part of the provided rib frame parts can have two legs that extend with distance to each other and are connected with the ring frame part in each case. The legs can extend from the ring frame part in an orthogonal or oblique orientation. The legs of the rib frame part are connected with one another by means of a transverse leg of the rib frame part. The transverse leg is arranged with distance to the ring frame part. In doing so, the rib frame part can particularly comprise a U-shape or V-shape or bracket shape.

It is in addition advantageous, if one of the legs and/or the transverse leg of the at least one rib frame part abuts against the housing body. The at least one leg and/or the transverse leg can thereby abut directly against one of the adjacent housing walls of the housing body or can be releasably or non-releasably connected with the adjacent housing wall.

It is in addition preferred, if multiple rib frame parts are provided that can extend parallel to one another. The rib frame parts are arranged with distance to each other orthogonal to their respective extension plane. Thereby the housing body can be supported in defined distances by means of the rib frame parts.

In another embodiment of the explosion-proof housing the reinforcing frame can consist exclusively of the ring frame part.

The at least one rib frame part and/or the ring frame part can be made of multiple frame struts that are connected with each other. Directly adjacent frame struts preferably abut against each other or are releasably or non-releasably connected with each other. Particularly directly adjacent frame struts can abut with their respectively assigned ends against each other or can be connected with each other by means of an adhesive layer or a substance bond layer, e.g. by means of gluing, welding or brazing. Directly adjacent frame struts can also be releasably or non-releasably connected with each other in any other arbitrary manner. A non-releasable connection can be established in addition or as an alternative to an adhesive bond and/or a substance bond, also by mechanical means, e.g. by means of rivets.

It is in addition advantageous, if the housing body comprises a housing flange. The housing flange extends preferably completely around the housing opening. The housing flange delimits the flameproof gap together with an opposite edge region of the cover. The edge region of the cover preferably abuts directly against the housing flange. Preferably, if the cover is in the closing position, cover and housing flange are pressed against each other by means of suitable connection means, e.g. screws or clamps.

Preferably a housing flange can be supported on the ring frame part, particularly directly abut against the ring frame part. Thereby the housing flange can be arranged between the ring frame part and the cover. The housing flange can abut against the ring frame part in circumferential direction around the housing opening over its entire circumferential length and/or transverse to this direction over its entire width. In addition or as an alternative, the ring frame part can abut against one side wall or multiple side walls of the housing body at one or multiple locations.

### BRIEF DESCRIPTION OF THE DRAWINGS

Advantageous embodiments of the invention are derived from the dependent claims, the description and the drawings. In the following preferred embodiments of the invention are explained in detail with reference to the attached drawings. The drawings show:

FIG. 1 an embodiment of an explosion-proof housing in a perspective view with view obliquely on a cover of the explosion-proof housing,

FIG. 2 the embodiment of the explosion-proof housing of FIG. 1 in another perspective illustration with view obliquely on a backside of the explosion-proof housing opposite the cover,

FIG. 3 an enlarged illustration of a part of a corner region III of the explosion-proof housing of FIG. 2,

FIG. 4 a cross-section illustration through the corner region of the explosion-proof housing of FIG. 3,

FIG. 5 a side view of an embodiment of an explosion-proof housing,

FIG. 6 a schematic basic illustration of a pressure relief device for forming a gas flow path between the interior of the housing and an environment on the outside around the housing,

FIG. 7 another embodiment of an explosion-proof housing in a perspective explosion illustration and

FIG. 8 another embodiment of an explosion-proof housing in a perspective illustration.

### DETAILED DESCRIPTION

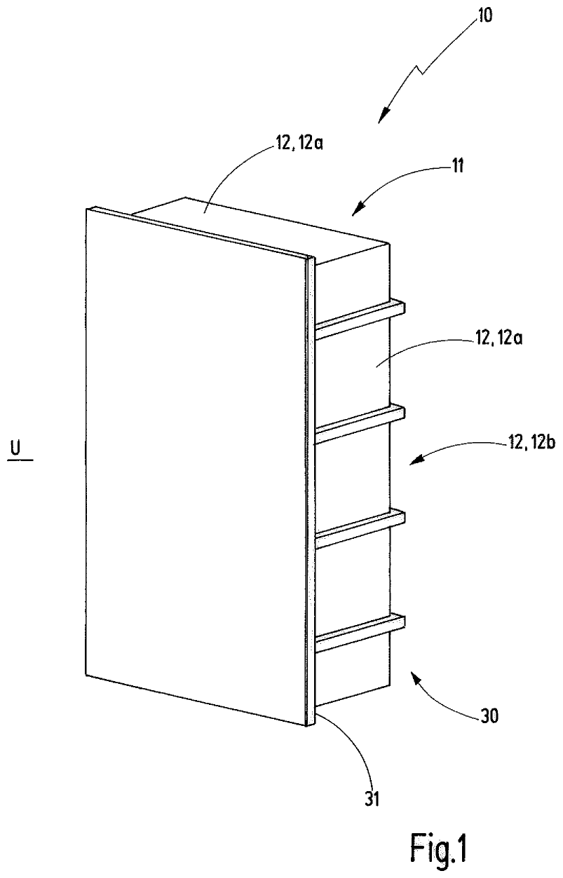

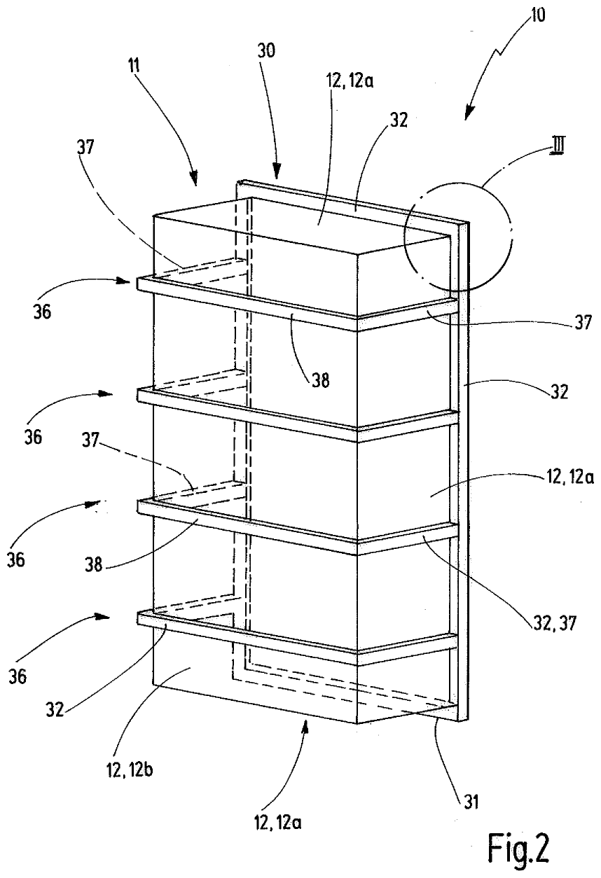

Different embodiments of an explosion-proof housing 10 are shown in FIGS. 1, 2, 5, 7 and 8. The explosion-proof housing 10 has a housing body 11 comprising one or multiple housing walls 12. In the embodiment the housing body comprises one or multiple side walls 12a as well as a back wall 12b. The number of side walls 12a can depend from the shape of the housing body 11. For example, one single circular ring-shaped side wall 12a can be provided. In the preferred embodiment described herein, the housing body 11 has four side walls 12a and a substantially cuboid-shaped contour.

All present side walls 12a are connected with back wall 12b. The housing walls 12 are non-releasably connected with one another in the embodiments illustrated here. Preferably the housing walls 12 are connected with each other by means of an adhesive bond or a substance bond, e.g. by gluing, welding, brazing or a combination thereof.

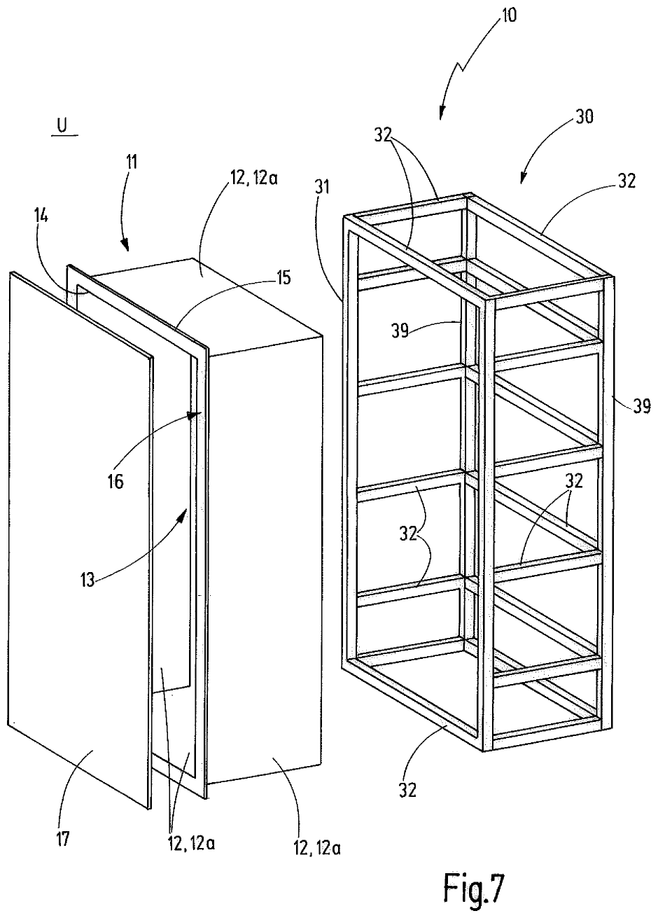

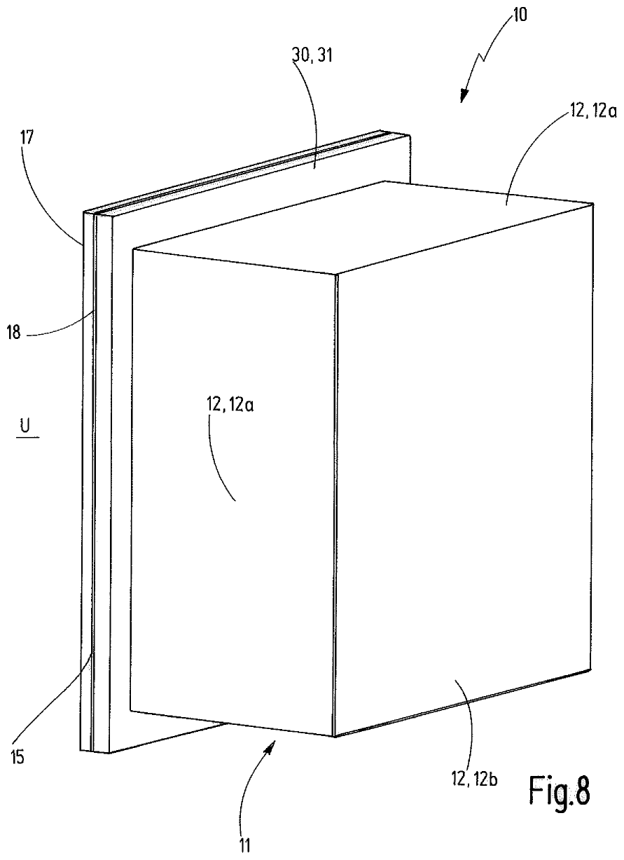

The housing body 11 delimits an interior 13 of the explosion-proof housing apparent from FIG. 7. In the interior 13 potential ignition sources can be located. Such potential ignition sources can be, for example, electrical and/or electronic devices or operating means.

The interior 13 is accessible by means of a housing opening 14 on one side. According to the example, housing opening 14 is located on the side of housing body 11 opposite the back wall 12b and is limited by housing body 11. A housing flange 15 is present on housing body 11 that completely surrounds housing opening 14 in the embodiments described and illustrated herein. In the embodiment housing flange 15 has several sections, wherein each section of housing flange 15 adjoins one side wall 12a of housing body 11 respectively.

In the embodiment each section of housing flange 15 can be configured integrally with one housing wall 12 or side wall 12a respectively or can be connected with the adjoining side wall 12a by means of adhesive bond or by means of substance bond. The sections of housing flange 15 that adjoin one another in circumferential direction around the housing opening 14 are either integrally configured or connected with one another by means of substance bond or adhesive bond.

If in the present application a substance bond or adhesive bond is mentioned, this connection can be established, e.g. by welding and/or gluing and/or brazing.

The housing flange 15 projects with view from the housing opening 14 outwardly and not into housing opening 14. The housing flange 15 forms a first delimiting surface 16 that preferably extends along one plane.

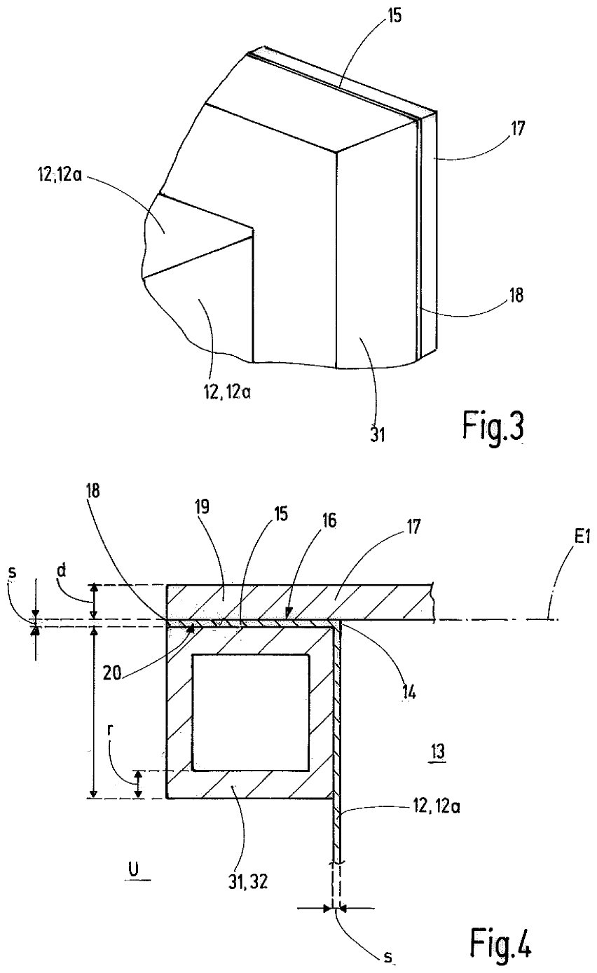

In order to separate the interior 13 from the environment U in an explosion-proof or flameproof manner, the explosion-proof housing 10 comprises in addition a cover 17. In a closing position (FIGS. 1, 2, 3, 5 and 8) cover 17 abuts against housing body 11 and according to the example against housing flange 15 such that between cover 17 and housing body 11 a flameproof gap 18 is formed (FIGS. 3, 4, 5 and 8).

For forming the flameproof gap 18, an edge region 19 of cover 17 is arranged opposite housing flange 15, wherein a second delimiting surface 20 is formed on the edge region 19. The flameproof gap 18 is delimited by the first delimiting surface 16 on housing flange 15 and by the second delimiting surface 20 on edge region 19 of cover 17. In the closing position of cover 17, the cover 17 and the housing flange 15 and thus first delimiting surface 16 and second delimiting surface 20 are pressed against one another. The force for this purpose can be created by respective connection means, such as screws and/or clamps or similar. The delimiting surfaces 16, 20 delimiting the flameproof gap 18 are illustrated in FIG. 4.

It is also apparent from FIG. 4 that the first delimiting surface 16 and the second delimiting surface 20 extend parallel to each other in a first plane E1, if cover 17 is in the closing position. The flameproof gap 18 is thus also located in this first plane E1.

In order to be able to manufacture the housing body 11 in a light-weight manner as far as possible with low material consumption, the wall thickness s of housing walls 12 or flange 15 is small and in the embodiment remarkably smaller than the thickness d of cover 17 (FIG. 4). The wall thickness s of housing walls 12 and flange 15 can be, for example, at least 3 to 4 times smaller than the thickness d of cover 17. In order to stabilize housing body 11 such that it withstands an explosion pressure in the interior 13 of explosion-proof housing 10, the explosion-proof housing comprises a reinforcing frame 30. The reinforcing frame 30 is releasably or non-releasably connected with housing body 11. For releasable connection the reinforcing frame 30 can be connected with housing body 11 by means of a screwed connection or another form-fit and/or force-fit connection. Preferably, the reinforcing frame 30 is non-releasably connected with housing body 11, e.g. by means of a substance bond and/or an adhesive bond, as for example, by means of welding and/or brazing and/or gluing. In addition or as an alternative, reinforcing frame 30 can also be connected with housing body 11 by means of a rivet connection.

Reinforcing frame 30 comprises a ring frame part 31 that extends completely around housing opening 14 adjacent to the flameproof gap 18. In the simplest case reinforcing frame 30 can consist of ring frame part 31 (FIG. 8).

The reinforcing frame 30 is arranged outside interior 13 and in addition connected with housing body 11. A direct contact and/or direct connection between reinforcing frame 30 and cover 17 does not exist in the embodiment. The flange 15 is arranged between ring frame part 31 of reinforcing frame 30 and cover 17 and thus separates ring frame part 31 from cover 17 such that a direct connection or direct contact does not exist. It is however possible that the reinforcing frame 30 is configured to cooperate with a connection means in order to attach cover 17 in its closing position on housing body 11. For example, contact surfaces for clamps or holders can be provided on the reinforcing frame 30 or ring frame part 31. In addition or as an alternative, threaded receptacles for threaded bolts can be provided on the reinforcing frame 30 or the ring frame part 31 by means of which cover 17 can be held in its closing position.

It is apparent from the drawings, e.g. FIGS. 3 and 4, that ring frame part 31 supports housing flange 15 along its entire circumferential length in circumferential direction around housing opening 14. The ring frame part 31 can support housing flange 15 transverse to the circumferential direction along its entire width (FIGS. 3 and 4) or only along a section. The ring frame part 31 preferably abuts against side walls 12a of housing body 11 adjoining housing flange 15 at one or multiple locations or along its entire extension.

According to the example, ring frame part 31 or reinforcing frame 30 is made of multiple frame struts 32 that are preferably configured as hollow profile struts respectively (FIG. 4). Preferably, the frame struts 32 have a polygonal cross-section contour that can be square or rectangular in the embodiment. The frame struts 32 have a frame wall thickness r that is larger than the wall thickness s of housing walls 12 or housing flange 15. The frame wall thickness r can be less than the thickness d of cover 17 or approximately equal to thickness d of cover 17.

For configuration of ring frame part 31, multiple frame struts 32 and according to the example four frame struts 32 are connected with each other. Two respectively directly adjacent frame struts are thereby connected with one another with their ends assigned to one another, e.g. by means of a substance bond and/or adhesive bond. In the embodiment the ring frame part 31 has a rectangular shape. In case of cylindrical frame bodies 11, the ring frame part 31 can also have a circular form and can be configured from at least one frame strut 32 forming a closed circular ring.

In the embodiments according to FIGS. 1-7 the reinforcing frame 30 comprises at least one rib frame part 36 in addition to the ring frame part 31. In the embodiments according to FIGS. 1, 2 and 5 four rib frame parts 36 are present. In the embodiment of FIG. 7 six rib frame parts 36 are present. The number of rib frame parts 36 can vary depending on the size of the housing body 11.

Each rib frame part 36 has two legs 37 that are arranged with distance to one another and can be arranged parallel to one another, for example. Each of the two legs 37 is connected with the ring frame part 31, e.g. by means of an adhesive bond and/or a substance bond. The two legs 37 are arranged on opposite sides relative to the housing opening 14 or relative to the housing body 11.

With distance to ring frame part 31 and according to the example, on ends opposite to ring frame part 31 the two legs 37 of a common rib frame part 36 are connected with each other by means of a transverse leg 38. The transverse leg 38 can be connected with legs 37 by means of a substance bond and/or adhesive bond.

In the embodiment the at least one rib frame part 36 has therefore a bracket-shaped form. Different to the preferred embodiment, the two legs 37 do not have to be parallel to each other. Preferably, the legs 37 extend along and parallel to the directly adjacent side wall 12a of housing body 11 and are adapted in their extension to the shape of the side wall 12a.

In the embodiment shown in FIGS. 1, 2 and 5, the rib frame parts 36 are exclusively connected with each other by the common ring frame part 31 of reinforcing frame 30. Additional frame struts 32 that extend between rib frame parts 36 and are not part of ring frame part 31 can be omitted.

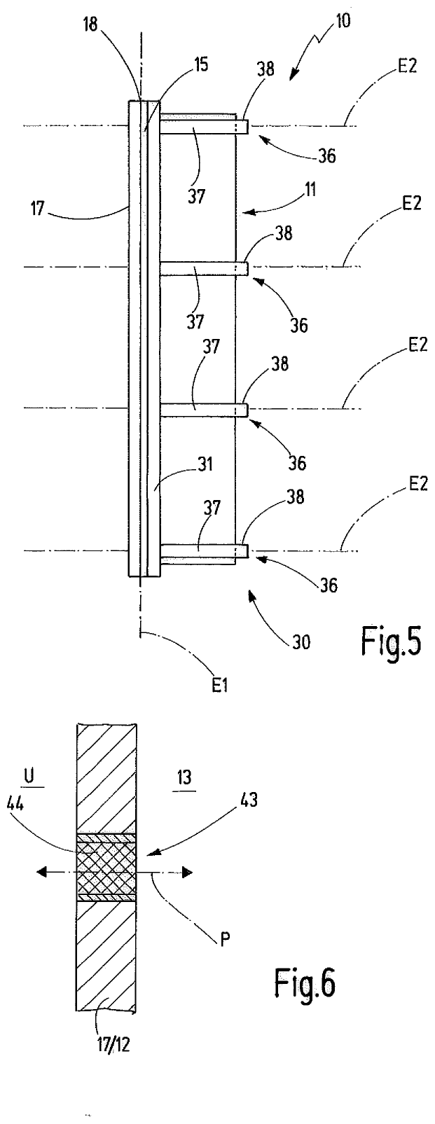

The rib frame parts 36 extend in a second plane E2 in each case, wherein each second plane E2 is orientated orthogonal to the first plane E1 in the embodiment (compare for example FIG. 5). Orthogonal to the second planes E2, the rib frame parts 36 are arranged with distance to one another. The distances between two directly adjacent rib frame parts 36 can have equal lengths (FIGS. 1, 2 and 5). The distances between two directly adjacent rib frame parts 36 orthogonal to the respective extension plane (second plane E2) can also have different lengths, as illustrated in FIG. 7.

In the embodiment illustrated in FIG. 7 the rib frame parts 36 are connected with each other by additional frame connections 39 of reinforcing frame 30, independent from ring frame part 31. According to the example, two frame connections 39 are present that are respectively made of at least one frame strut 32 that extends parallel to the first plane E1 or parallel to ring frame part 31 and that connects the rib frame part 36 in the corner regions between a leg 37 and the transverse leg 38 with each other. In the embodiment two frame connections 39 extending parallel to one another are present to each of which the transverse legs 38 and the legs 37 are attached respectively, e.g. by means of a substance bond and/or adhesive bond. In the embodiment the frame connections 39 extend orthogonal to legs 37 and transverse legs 38 of the rib frame parts 36.

In the preferred embodiment illustrated here all of the frame struts 32 extend in a direction x or a direction y or a direction z of a Cartesian coordinate system. In modification thereto the reinforcing frame 30 could also comprise at least one frame strut 32 that extends obliquely to the direction x and/or obliquely to the direction y and/or obliquely to the direction z of the Cartesian coordinate system.

A gas exchange can occur between interior 13 and the environment U. Thus it cannot be excluded that explosive gases enter the interior 13 and are ignited to explode by an ignition source arranged in the interior 13. The flameproof gap 18 is configured or dimensioned such that hot gases, light arcs, flames, sparks or other ignitable media are sufficiently cooled or extinguished before they reach the environment U when leaving the interior 13. In doing so, it is ensured that an ignition of the explosive atmosphere in the environment U around the explosion-proof housing 10 is avoided. Due to the reinforcing frame 30, it is ensured that the housing body 11 does not deform, because of the explosion pressure such that the flameproof condition of the flameproof gap 18 is abolished. This is particularly guaranteed by ring frame part 31 that is arranged directly adjacent to housing opening 14. The housing flange 15 is supported on ring frame part 31. In doing so, an impairment of the flameproof gap 18 in case of an explosion in the interior 13 is avoided. The ring frame part 31 can be strengthened by one or more rib frame parts 36 in order to avoid a deformation of the ring frame part 31 in case of an explosion in the interior 13.

In the preferred embodiments described so far, a gas flow connection between interior 13 and environment U exists exclusively via the flameproof gap 18. In modification thereto the explosion-proof housing 10 can comprise at least one pressure relief device 43 as an option that is schematically illustrated in FIG. 6. By means of the at least one pressure relief device 43 at least one additional flameproof gas flow path P can be provided between interior 13 and environment U. For example, the pressure relief device 43 can consist of an insert that is arranged in cover 17 or a housing wall 12 of housing body 11. For establishing a flameproof condition of a gas flow path P, the pressure relief device 43 can comprise a gas permeable porous body 44, for example. Also other configurations of pressure relief devices 43 can be used as they are per se known in explosion-proof housings. By means of the at least one pressure relief device 43, the explosion pressure in the interior 13 can be additionally limited.

The at least one gas flow path P of the at least one pressure relief device 43 does not extend through any frame strut 32 of reinforcing frame 30, but extends in areas between frame struts 32 of reinforcing frame 30. Thus, all of the components of reinforcing frame 30 are free of sections of the at least one flameproof gas flow path P.

In the embodiments described here the explosion-proof housing 10 is configured in the explosion protection type flameproof enclosure (Ex d). The explosion-proof housing 10 could be alternatively configured also in other standardized explosion protection types.

The invention refers to an explosion-proof housing 10 having a housing body 11 that delimits an interior 13 and comprises a housing opening 14. By means of a cover 17, the housing opening 14 can be closed. In the closing position of cover 17 a flameproof gap 18 is created between housing body 11 and particularly a housing flange 15 of housing body 11 and cover 17. The housing body 11 comprises multiple housing walls 12 that have such a small wall thickness s that the housing walls 12 would not withstand an explosion pressure in the interior 13. The housing body 11 is, therefore, reinforced by a reinforcing frame 30 arranged outside interior 13. The reinforcing frame 30 comprises a ring frame part 31 that is arranged adjacent to the housing opening 14 and that completely surrounds housing body 11 in a ring-shaped manner. Particularly, ring frame part 31 directly adjoins housing flange 15.

### LIST OF REFERENCE SIGNS

10 explosion-proof housing
11 housing body
12 housing wall
12a side wall
12b back wall
13 interior
14 housing opening
15 housing flange
16 first delimiting surface
17 cover
18 flameproof gap
19 edge region
20 second delimiting surface
30 reinforcing frame
31 ring frame part
32 frame strut
36 rib frame part
37 leg
38 transverse leg
39 frame connection
43 pressure relief device
44 porous body
d thickness of cover
P gas flow path
r frame wall thickness
s wall thickness
U environment

1. An explosion-proof housing, comprising:
a housing body that delimits an interior and that comprises a housing opening through which the interior is accessible;
a reinforcing frame that is arranged on an outside of the housing body and comprises a ring frame part that completely surrounds the housing body in a ring-shaped manner adjacent to the housing opening;
a cover that abuts against the housing body in a closing position, such that a flameproof gap is formed between the cover and the housing body.

2. The explosion-proof housing according to claim 1, wherein at least one pressure relief device is provided, the at least one pressure relief device forms at least one flameproof gas flow path between the interior and an environment outside of housing.

3. The explosion-proof housing according to claim 2, wherein the reinforcing frame is free of sections of the at least one flameproof gas flow path.

4. The explosion-proof housing according to claim 1, wherein a gas flow connection between the interior and an environment outside of housing is exclusively provided by the flameproof gap.

5. The explosion-proof housing according to claim 1, wherein the reinforcing frame comprises at least one rib frame part that is connected with the ring frame part and that extends outside of a plane defined by ring frame part.

6. The explosion-proof housing according to claim 5, wherein the at least one rib frame part comprises two legs that extend with distance to one another and that are respectively connected with the ring frame part, and that the at least one rib frame part comprises a transverse leg that extends with distance to the ring frame part and that connects the two legs with each other.

7. The explosion-proof housing according to claim 6, wherein the two legs and/or the transverse leg of the at least one rib frame part abuts against the housing body.

8. The explosion-proof housing according to claim 5, wherein the at least one rib frame part comprises multiple rib frame parts that extend parallel to each other and that are arranged with distance to each other.

9. The explosion-proof housing according to claim 5, wherein the at least one rib frame part is made respectively from multiple frame struts connected with each other.

10. The explosion-proof housing according to claim 1, wherein the ring frame part is respectively made from multiple frame struts connected with each other.

11. The explosion-proof housing according to claim 9, wherein the multiple frame struts abut each other with their ends.

12. The explosion-proof housing according to claim 9, wherein the multiple frame struts are non-releasably connected with each other.

13. The explosion-proof housing according to claim 1, wherein the housing body includes a housing flange and that the flameproof gap is formed between the cover and the housing flange.

14. The explosion-proof housing according to claim 13, wherein the housing flange extends completely around the housing opening.

15. The explosion-proof housing according to claim 13, wherein the housing flange is supported on the ring frame part.

16. The explosion-proof housing according to claim 3, wherein the reinforcing frame comprises at least one rib frame part that is connected with the ring frame part and that extends outside of a plane defined by ring frame part.

17. The explosion-proof housing according to claim 16, wherein the at least one rib frame part comprises two legs that extend with distance to one another and that are respectively connected with the ring frame part, and that the at least one rib frame part comprises a transverse leg that extends with distance to the ring frame part and that connects the two legs with each other.

18. The explosion-proof housing according to claim 17, wherein the two legs and/or the transverse leg of the at least one rib frame part abuts against the housing body.

19. The explosion-proof housing according to claim 18, wherein the at least one rib frame part comprises multiple rib frame parts that extend parallel to each other and that are arranged with distance to each other.

20. The explosion-proof housing according to claim 19, wherein the at least one rib frame part is made respectively from multiple frame struts connected with each other.
